(19) United States
(12) Patent Application Publication
(10) Pub. No.: US 2025/0076765 A1
(43) Pub. Date: Mar. 6, 2025

(54) RESIST TOPCOAT COMPOSITION, AND METHOD OF FORMING PATTERNS USING THE COMPOSITION

(71) Applicant: SAMSUNG SDI CO., LTD., Yongin-si (KR)

(72) Inventors: Daeseok SONG, Suwon-si (KR); Ran NAMGUNG, Suwon-si (KR); Kyoungjin HA, Suwon-si (KR); Hyeon PARK, Suwon-si (KR); Minsoo KIM, Suwon-si (KR)

(21) Appl. No.: 18/794,952

(22) Filed: Aug. 5, 2024

(30) Foreign Application Priority Data
Aug. 29, 2023 (KR) 10-2023-0113817

(51) Int. Cl. G03F 7/11; G03F 7/16

(52) U.S. Cl. CPC G03F 7/11; G03F 7/161; G03F 7/168

(57) ABSTRACT

Provided are a resist topcoat composition and a method of forming patterns using the resist topcoat composition, the resist topcoat composition including a copolymer including a first structural unit represented by Chemical Formula M-1, a second structural unit represented by Chemical Formula M-2; at least one acidic compound selected from a sulfonic acid compound containing at least one fluorine, a sulfonimide compound containing at least one fluorine, and a carboxylic acid compound containing at least one fluorine; and a solvent.

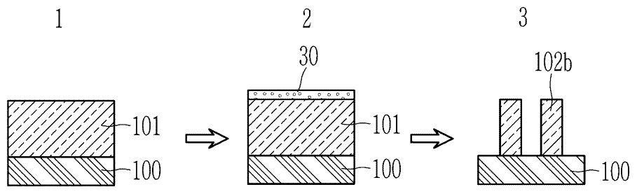

### CROSS-REFERENCE TO RELATED APPLICATION

The present application claims priority to and the benefit of Korean Patent Application No. 10-2023-0113817, filed on Aug. 29, 2023, in the Korean Intellectual Property Office, the entire disclosure of which is hereby incorporated by reference.

### BACKGROUND

### 1. Field

Embodiments of this disclosure relate to a resist topcoat composition and a method of forming a pattern using the same.

### 2. Description of the Related Art

Recently, the semiconductor industry has developed an ultrafine technique that provides a pattern of several to several tens of nanometers in size. Such ultrafine technique should be accompanied by effective photolithographic processes.

Existing photolithographic processes involve forming a material layer on a semiconductor substrate, coating a photoresist layer thereon, exposing and developing to form a photoresist pattern, and then etching the material layer using the photoresist pattern as a mask.

As photolithography processes develop, a degree of pattern integration is increasing, and materials and technologies for solving various problems occurring in this process are being investigated.

For example, if extreme ultraviolet (EUV) is irradiated to the photoresist, because there may be a region where a large amount or a small amount of light is randomly irradiated due to a large energy per photon of EUV light, which may be referred to as a photo shot noise, or an EUV absorption difference between top and bottom of the photoresist may cause pattern dispersion deterioration such as roughness (e.g., LER: line edge roughness, LWR: line width roughness) and/or IPU (in-point uniformity) of the patterns, and thus, it would be useful to further develop technology to improve this pattern dispersion deterioration.

### SUMMARY

Some embodiments of the present disclosure provide a resist topcoat composition capable of reducing pattern dispersion by preventing or reducing pattern deterioration.

Some embodiments provide a method of forming patterns using the resist topcoat composition.

Some embodiments provide the resist topcoat composition including a copolymer including a first structural unit represented by Chemical Formula M-1, a second structural unit represented by Chemical Formula M-2, at least one acidic compound selected from a sulfonic acid compound containing at least one fluorine, a sulfonimide compound containing at least one fluorine, and a carboxylic acid compound containing at least one fluorine; and a solvent.

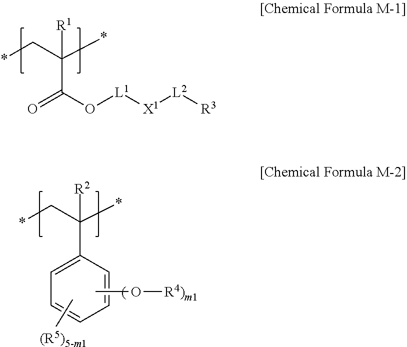

In Chemical Formula M-1 and Chemical Formula M-2,
R¹ and R² are each independently hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen or C(═O)R^{b},
R^{b} is a substituted or unsubstituted C1 to C10 alkyl group,
at least one selected from R³, L¹, and L² includes fluorine and a hydroxy group,
R⁵ is hydrogen, a halogen, a hydroxy group, a substituted or unsubstituted C1 to C10 alkyl group, or a combination thereof,
m1 is one of integers of 1 to 4, and
* is a linking point (e.g., a linking point to another portion of the copolymer).

Some embodiments provide a method of forming patterns which includes coating and heating a photoresist composition on a substrate to form a photoresist layer, coating and heating the aforementioned resist topcoat composition on the photoresist layer to form a topcoat, and exposing and developing the topcoat and the photoresist layer to form a resist pattern.

The resist topcoat composition according to some embodiments may remove excessively activated acid from the top of the photoresist, if exposed with EUV, to prevent or reduce deterioration of the pattern dispersion such as, for example, roughness (LER, LWR) and/or IPU of the patterns due to EUV absorption differences between a top and a bottom of a photoresist, thereby improving the pattern dispersion, significantly improving IPU of pillar patterns, and contributing to forming fine patterns of the photoresist.

### BRIEF DESCRIPTION OF THE DRAWING

The accompanying drawing, together with the specification, illustrates embodiments of the subject matter of the present disclosure, and, together with the description, serve to explain principles of embodiments of the subject matter of the present disclosure.

The accompanying drawing is a schematic view illustrating a method of forming patterns using a resist topcoat composition according to some embodiments.

### DETAILED DESCRIPTION

Hereinafter, embodiments of the present disclosure will be described in detail so that those skilled in the art can easily implement the subject matter of the present disclosure. However, this disclosure may be embodied in many different forms and is not construed as limited to the example embodiments set forth herein.

In the drawing, the thickness of layers, films, panels, regions, etc., are exaggerated for clarity and like reference numerals designate like elements throughout the specification. It will be understood that if an element such as a layer, film, region, or substrate is referred to as being “on” another element, it can be directly on the other element or intervening elements may also be present. In some embodiments, if an element is referred to as being “directly on” another element, there are no intervening elements present.

As used herein, if a definition is not otherwise provided, “substituted” refers to replacement of a hydrogen atom of a compound by a substituent selected from a halogen atom (F, Br, Cl, or I), a hydroxy group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, if a definition is not otherwise provided, the term “an alkyl group” refers to a linear or branched aliphatic hydrocarbon group. The alkyl group may be “a saturated alkyl group” without any double bond or triple bond (e.g., the alkyl group does not include any double bond or triple bond).

The alkyl group may be a C1 to C8 alkyl group. In some embodiments, the alkyl group may be a C1 to C10 alkyl group or a C1 to C6 alkyl group. For example, the term C1 to C5 alkyl group may refer to an alkyl chain that contains 1 to 5 carbon atoms and is selected from methyl, ethyl, propyl, iso-propyl, n-butyl, iso-butyl, sec-butyl, and tert-butyl.

The alkyl group may include examples such as a methyl group, an ethyl group, a propyl group, an isopropyl group, a butyl group, an isobutyl group, a tert-butyl group, a pentyl group, a hexyl group, and the like.

In chemical formulas described herein, t-Bu refers to a tert-butyl group.

As used herein, if a definition is not otherwise provided, “cycloalkyl group” refers to a monovalent cyclic aliphatic hydrocarbon group.

The term cycloalkyl group refers to a cyclopropyl group, a cyclobutyl group, a cyclopentyl group, a cyclohexyl group, and/or the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

As used herein, the term “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms) functional group.

As used herein, if a definition is not otherwise provided, “hetero” refers to one including 1 to 3 heteroatoms selected from N, O, S, Se, and P.

In the present disclosure, if a definition is not otherwise provided, the term “heterocycloalkyl group” refers to a cycloalkyl group containing at least one hetero atom selected from N, O, S, P, and Si.

In the present disclosure, the term “heteroaryl group” refers to an aryl group including at least one hetero atom selected from N, O, S, P, and Si. Two or more heteroaryl groups are linked by a sigma bond directly, or if the heteroaryl group includes two or more rings, the two or more rings may be fused together. If the heteroaryl group is a fused ring, each ring may include 1 to 3 hetero atoms.

Unless otherwise specified in the present specification, the weight average molecular weight may be measured by dissolving a powder sample in tetrahydrofuran (THF) and then using 1200 series Gel Permeation Chromatography (GPC) of Agilent Technologies (column may be Shodex Company LF-804, standard sample may be Shodex company polystyrene).

In some embodiments, unless otherwise defined in the specification, “*” indicates a linking point of a structural unit or a compound moiety of a compound.

Hereinafter, a resist topcoat composition according to some embodiments is described.

The present disclosure relates to a photoresist topcoat composition capable of improving IPU (in-point uniformity) of C/H (contact hole) patterns, LER (line edge roughness)/LWR (line width roughness) of L/S (line and space) patterns, and IPU of pillar patterns by improving sensitivity of a photoresist during the fine pattern-forming process of photolithography using high-energy rays such as EUV (extreme ultraviolet; wavelength: about 13.5 nm) and/or the like and concurrently (e.g., simultaneously), selectively reducing an acid concentration of the upper portion of the photoresist and a method of forming photoresist patterns by using this topcoat.

The photoresist topcoat composition according to some embodiments includes a copolymer including a first structural unit represented by Chemical Formula M-1, a second structural unit represented by Chemical Formula M-2; at least one acidic compound selected from a sulfonic acid compound containing at least one fluorine, a sulfonimide compound containing at least one fluorine, and a carboxylic acid compound containing at least one fluorine; and a solvent.

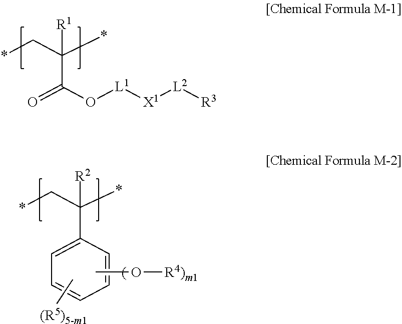

In Chemical Formula M-1 and Chemical Formula M-2,
R¹ and R² are each independently hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen or C(═O)R^{b},
R^{b} is a substituted or unsubstituted C1 to C10 alkyl group,

At least one selected from R³, L¹, and L² includes fluorine and a hydroxy group,
R⁵ is hydrogen, a halogen, a hydroxy group, a substituted or unsubstituted C1 to C10 alkyl group, or a combination thereof,
m1 is one of integers of 1 to 4, and
* is a linking point (e.g., a linking point to another portion of the copolymer).

The photoresist topcoat composition according to some embodiments may be coated on top of a photoresist layer to significantly improve LER/LWR of L/S patterns, IPU of C/H patterns, and IPU of pillar patterns as well as increase sensitivity of the photoresist.

The first structural unit included in the copolymer of the composition has characteristics of having almost no reactivity with the photoresist but being well dissolved in a solvent and thus may protect the photoresist, while minimizing or reducing an influence on the photoresist, and the second structural unit may increase EUV absorption to improve sensitivity.

Accordingly, the copolymer may have excellent solubility in solvents, be uniformly (or substantially uniformly) coated on a pattern, and minimize or reduce the effect on the resist.

In some embodiments, the acidic compound included in the composition is an acidic compound containing at least one fluorine, and may be for example selected from a sulfonic acid compound containing at least one fluorine, a sulfonimide compound containing at least one fluorine, and a carboxylic acid compound containing at least one fluorine.

In some embodiments, by adding an acidic compound containing at least one fluorine, defects in the resist may be selectively removed. In some embodiments, IPU or LWR of the pattern may be improved by making it rectangular by dissolving and removing a deteriorated region on the upper portion of the pattern that occurred during the exposure process, for example, a rounded profile region of the upper layer of the photoresist, during the development process.

The photoresist topcoat composition, if it remains after the development, may cause scum defects in the L/S patterns and/or not-open defects in the C/H patterns, thereby resulting in decreasing a product yield.

However, the photoresist topcoat composition according to some embodiments may be removed during the development process and thus cause no (or substantially no) defects in various suitable patterns.

The copolymer and the acidic compound may be included in a weight ratio of about 3:1 to about 30:1.

By including the copolymer and the acidic compound in the above weight ratio, the resist topcoat composition according to some embodiments may prevent or reduce pattern deterioration and reduce pattern dispersion.

The copolymer may be included in an amount of about 1 wt % to about 10 wt % based on a total weight of the resist topcoat composition.

The acidic compound may be included in an amount of about 0.1 wt % to about 10 wt % based on a total weight of the resist topcoat composition.

Within the above ranges, the resist topcoat may be easily removed.

As an example, the copolymer may include the first structural unit represented by Chemical Formula M-1 and the second structural unit represented by Chemical Formula M-2.

In Chemical Formula M-2, if m1 is 2 or more, each O—R⁴ may be the same or different from each other.

In Chemical Formula M-2, if 5-m1 is 2 or more, each R⁵ may be the same or different from each other.

The meaning that at least one of R³, L¹, and L² includes a fluorine and hydroxy group may include cases where
R³ may be a C1 to C20 alkyl group substituted with at least one fluorine and at least one hydroxy group, or
at least one selected from L¹ and L² may be a C1 to C10 alkylene group substituted with one or more fluorine and one or more hydroxy groups, or
at least one selected from L¹ and L² may be a C1 to C10 alkylene group substituted with one or more fluorine, and at least one selected from the others may be a C1 to C10 alkylene group substituted with one or more hydroxy groups, or
R³ may be fluorine, and at least one selected from L¹ and L² may be a C1 to C10 alkylene group substituted with one or more hydroxy groups, or
R³ may be a hydroxy group, and at least one selected from L¹ and L² may be a C1 to C10 alkylene group substituted with one or more fluorine, or
R³ may be a C1 to C10 alkyl group substituted with one or more fluorine and one or more hydroxy groups, or
R³ may be a C1 to C10 alkyl group substituted with one or more hydroxy groups and one or more C1 to C10 fluoroalkyl groups.

As an example, the first structural unit may be represented by Chemical Formula 1.

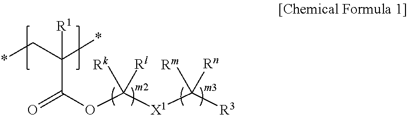

In Chemical Formula 1,
R¹ is hydrogen or a substituted or unsubstituted C1 to C10 alkyl group,
Rₖ, Rₗ, Rₘ, Rₙ, and R₃ are each independently hydrogen, fluorine, a hydroxy group, a substituted or unsubstituted C1 to C20 alkyl group, or a combination thereof,
m2 and m3 are each independently one of integers of 1 to 10,
X¹ is a single bond (e.g., a single covalent bond), —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof, and
at least one selected from Rₖ, Rₗ, Rₘ, Rₙ, and R₃ includes fluorine and a hydroxy group.

In Chemical Formula 1, if m2 is 2 or more, each Rₖ may be the same or different from each other.

In Chemical Formula 1, if m2 is 2 or more, each Rₗ may be the same or different from each other.

In Chemical Formula 1, if m3 is 2 or more, each Rₘ may be the same or different from each other.

In Chemical Formula 1, if m3 is 2 or more, each Rₙ may be the same or different from each other.

The recitation that at least one selected from Rₖ, Rₗ, Rₘ, Rₙ, and R₃ includes a fluorine and hydroxy group may include embodiments where:
at least one selected from R^{k}, R^{l}, R^{m}, Rⁿ, and R³ is each independently a fluorine and hydroxy group, or
at least one selected from R^{k}, R^{l}, R^{m}, Rⁿ, and R³ each independently includes a C1 to C10 alkyl group substituted with one or more fluorine and a C1 to C10 alkyl group substituted with one or more hydroxy groups, or
at least one selected from R^{k}, R^{l}, R^{m}, Rⁿ, and R³ each independently includes C1 to C10 alkyl groups substituted with one or more hydroxy groups and one or more fluorine, or
at least one selected from R^{k}, R^{l}, R^{m}, Rⁿ, and R³ each independently includes a C1 to C5 alkyl group substituted with one or more hydroxy groups and one or more C1 to C5 fluoroalkyl groups, or
at least one selected from R^{k}, R^{l}, R^{m}, Rⁿ, and R³ is fluorine, and at least one selected from the others is a hydroxy group, or
at least one selected from R^{k}, R^{l}, R^{m}, Rⁿ, and R³ is fluorine, and at least one selected from the others includes a C1 to C10 alkyl group substituted with one or more hydroxy groups, or
at least one selected from R^{k}, R^{l}, R^{m}, Rⁿ, and R³ is a hydroxy group, and at least one selected from the others includes a C1 to C10 alkyl group substituted with one or more fluorines, or
at least one selected from R^{k}, R^{l}, R^{m}, Rⁿ, and R³ is a C1 to C20 alkyl group substituted with one or more fluorine, and at least one selected from the others is a C1 to C20 alkyl group substituted with one or more hydroxy groups.

For example, R¹ may be hydrogen or a methyl group,
X¹ may be a single bond (e.g., a single covalent bond), —O—, or —NR^{a}— (wherein, R^{a} is hydrogen, deuterium, or a substituted or unsubstituted C1 to C10 alkyl group), and
R³ may be fluorine, a hydroxy group, a C1 to C10 alkyl group substituted with at least one fluorine, or a C1 to C10 alkyl group substituted with at least one hydroxy group.

As an example, in Chemical Formula 1, at least one selected from R^{m}, Rⁿ, and R³ may include a fluorine and a hydroxy group.

As an example, in Chemical Formula 1, at least one selected from R^{m} and Rⁿ may be fluorine or a C1 to C10 alkyl group substituted with at least one fluorine, and R³ may be a hydroxy group or a C1 to C10 alkyl group substituted with at least one hydroxy group.

As an example, in Chemical Formula 1, at least one selected from R^{m} and Rⁿ may be a hydroxy group or a C1 to C10 alkyl group substituted with at least one hydroxy group, and R³ may be fluorine or a C1 to C10 alkyl group substituted with at least one fluorine.

As an example, in Chemical Formula 1, R^{m} may be a hydroxy group or a C1 to C10 alkyl group substituted with at least one hydroxy group, Rⁿ may be fluorine or a C1 to C10 alkyl group substituted with at least one fluorine, and R³ may be a hydroxy group, fluorine, or a C1 to C10 alkyl group substituted with at least one of fluorine and hydroxy groups.

As an example, in Chemical Formula 1, at least one selected from R^{m} and Rⁿ may be fluorine or a C1 to C10 alkyl group substituted with at least one fluorine, and R³ may be a hydroxy group or a C1 to C5 alkyl group substituted with at least one selected from a hydroxy group and a C1 to C5 fluoroalkyl group.

For example, the first structural unit may be selected from Group I.

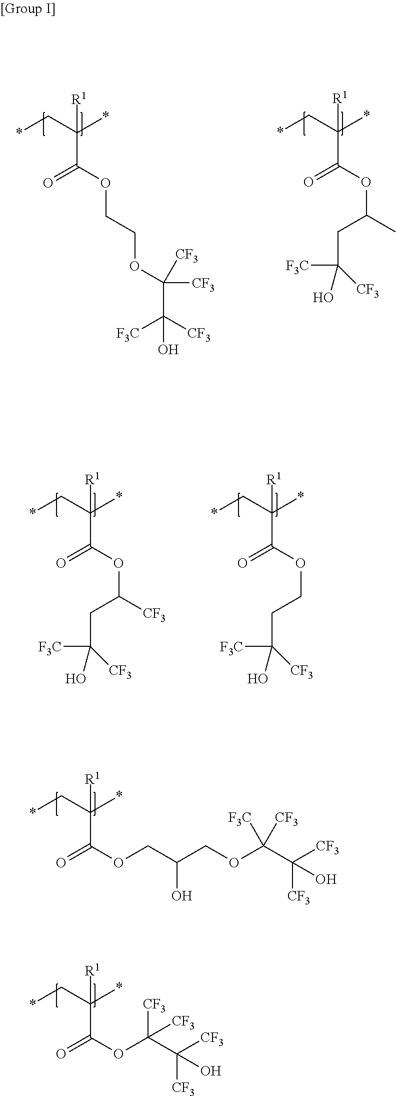

In Group I,
R¹ is each independently hydrogen or a methyl group and * is a linking point (e.g., * is a linking point to another portion of the copolymer).

As an example, the second structural unit may be represented by any one selected from Chemical Formula 2-1 to Chemical Formula 2-4.

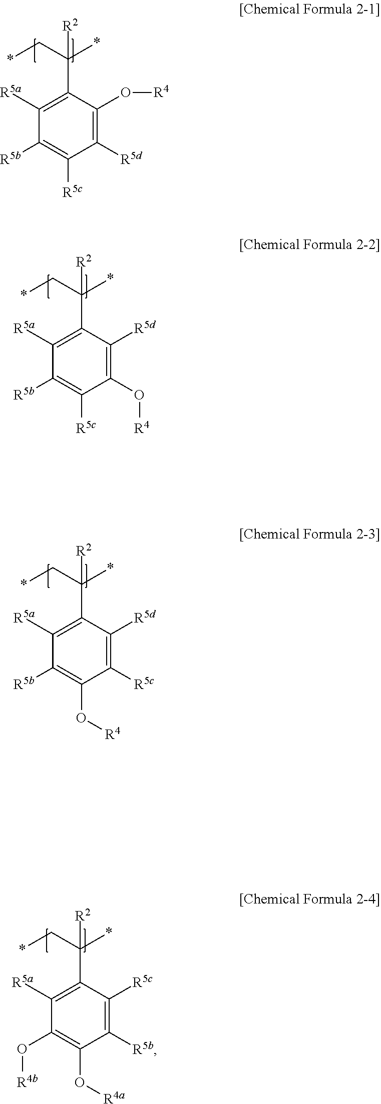

In Chemical Formula 2-1 to Chemical Formula 2-4,
R² is hydrogen or a methyl group,
R⁴, R^{4a}, and R^{4b} are each independently hydrogen or C(═O)R^{b},
R^{b} is a substituted or unsubstituted C1 to C5 alkyl group,
R^{5a}, R^{5b}, R^{5c}, and R^{5d} are each independently hydrogen, halogen, a hydroxy group, a substituted or unsubstituted C1 to C10 alkyl group, or a combination thereof, and
* is a linking point (e.g., * is a linking point to another portion of the copolymer).

As an example, at least one selected from R⁵ may be a halogen.

As an example, at least one selected from R⁵ may be an iodine group.

If the second structural unit includes an iodine group, sensitivity may be further improved.

For example, the second structural unit may be selected from Group Il.

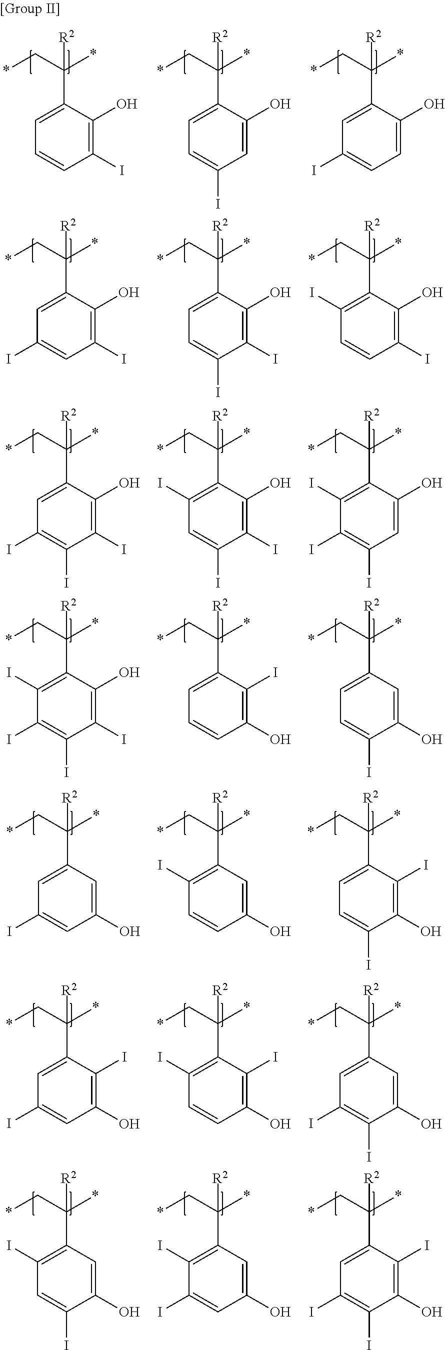

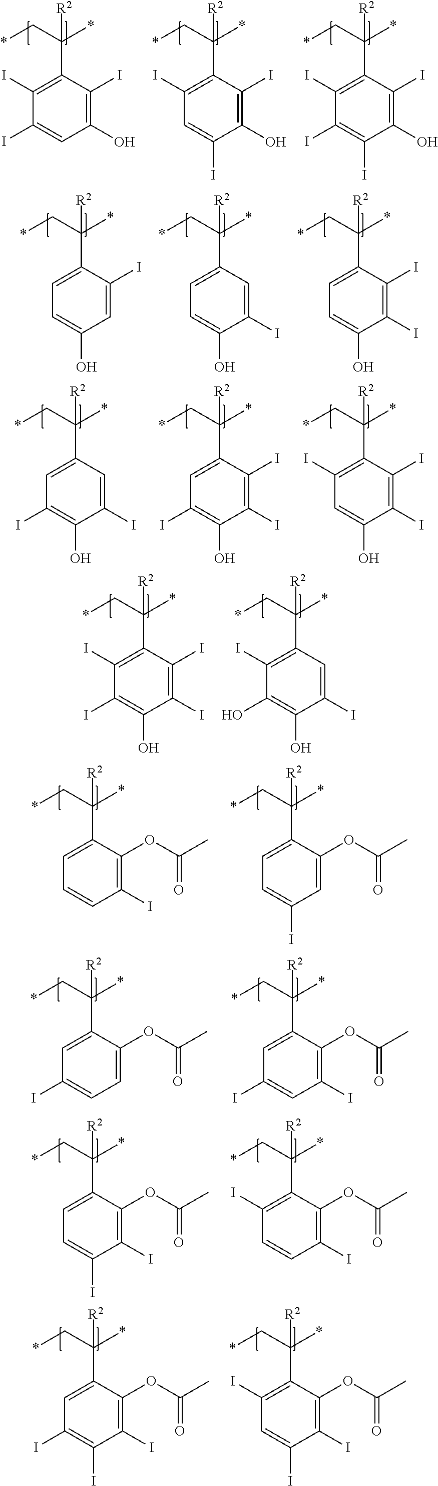

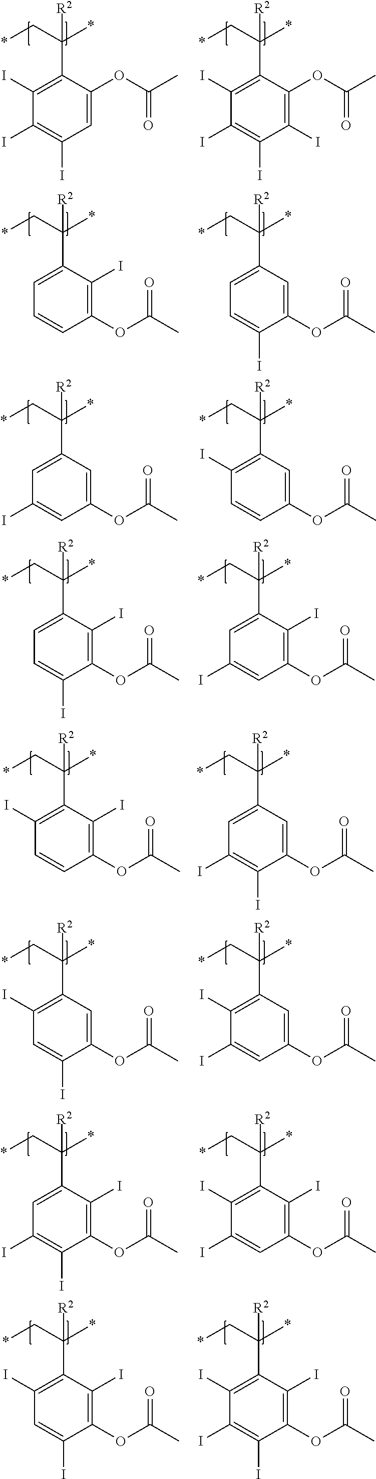

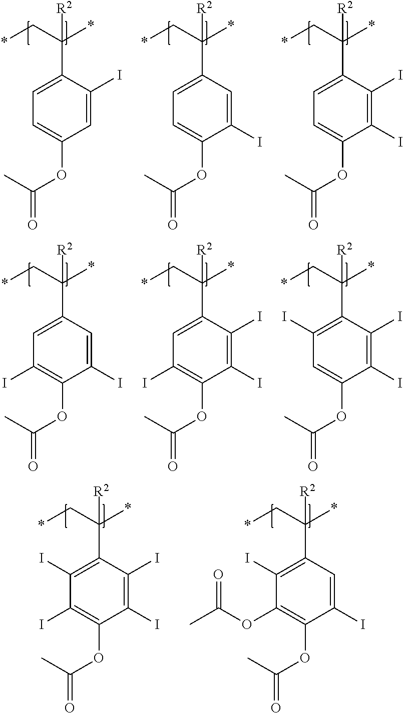

In Group II,
R² is each independently hydrogen or a methyl group and * is a linking point (e.g., * is a linking point to another portion of the copolymer).

The copolymer may include about 30 to about 95 mol % of the first structural unit, and about 5 to about 70 mol % of the second structural unit.

For example, the copolymer may include about 50 to about 90 mol % of the first structural unit, about 10 to about 50 mol % of the second structural unit, more specifically about 60 to about 85 mol % of the first structural unit, and about 15 to about 40 mol % of the second structural unit.

If the mole ratio of each structural unit included in the copolymer is within the above ranges, the solubility in organic solvents is improved and the pattern can be uniformly (or substantially uniformly) coated.

The copolymer may have a weight average molecular weight (Mw) of about 1,000 g/mol to about 50,000 g/mol. For example, the copolymer may have a weight average molecular weight of about 2,000 g/mol to about 30,000 g/mol, for example, about 3,000 g/mol to about 20,000 g/mol, but is not limited thereto. If the weight average molecular weight of the copolymer is within the above ranges, a carbon content and solubility in a solvent of the resist topcoat composition including the copolymer may be improved.

The copolymer may be included in an amount of about 1 wt % to about 10 wt % based on a total weight of the resist topcoat composition. Within the above range, the resist topcoat may be easily removed.

In some embodiments, the copolymer may be selected from those listed in Group III.

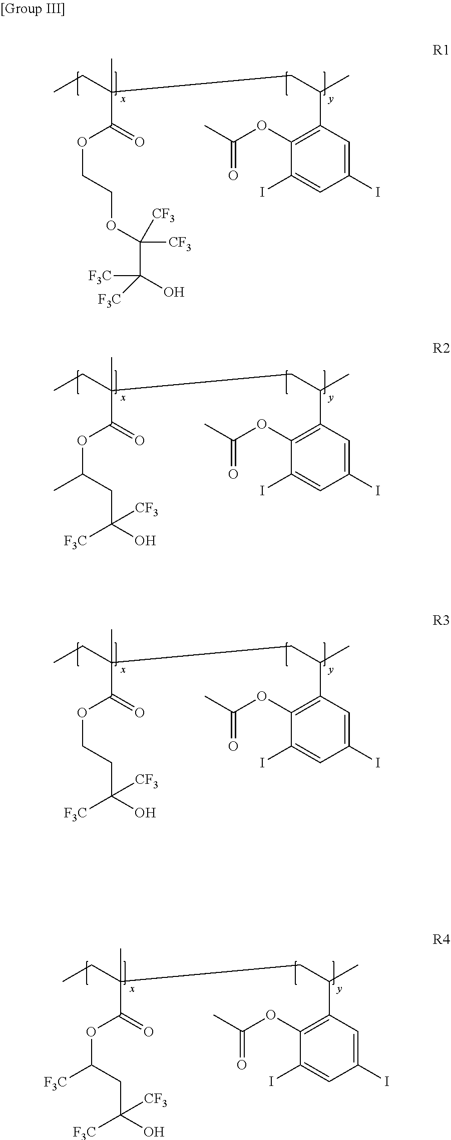

In Group III, x:y may be about 65:35, about 70:30, or about 75:25.

As an example, the acidic compound may be at least one selected from compounds represented by Chemical Formula 3 to Chemical Formula 6.

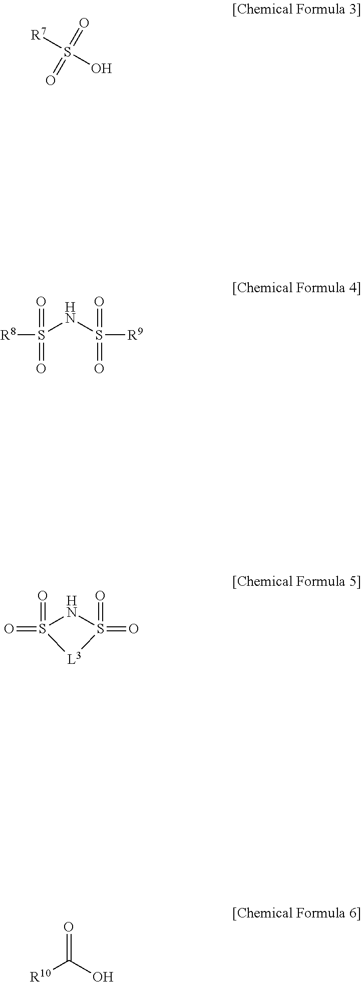

In Chemical Formula 3 to Chemical Formula 6,
R⁷ to R¹⁰ are each independently fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, a C1 to C20 heteroaryl group substituted with at least one fluorine, or a combination thereof, and
L³ is a C1 to C10 alkylene group substituted with at least one fluorine, a C3 to C20 cycloalkylene group substituted with at least one fluorine, a C6 to C20 arylene group substituted with at least one fluorine, a C1 to C20 heteroarylene group with at least one fluorine, or a combination thereof.

As an example, R⁷ to R¹⁰ in Chemical Formula 3 to Chemical Formula 6 are each independently a C1 to C10 alkyl group substituted with at least one fluorine, a C6 to C20 aryl group substituted with at least one fluorine, or a combination thereof, and
L³ may be a C1 to C5 alkylene group substituted with at least one fluorine.

For example, the acidic compound may be at least one selected from compounds listed in Group IV.

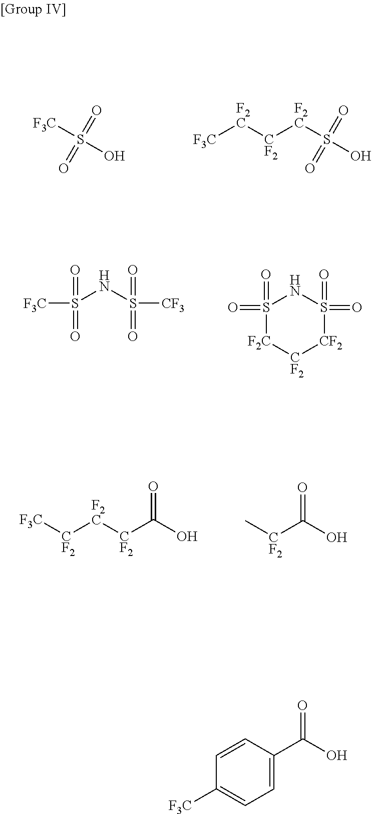

In some embodiments, the resist topcoat composition may further include at least one other polymer selected from an epoxy-based resin, a novolac resin, a glycoluril-based resin, and a melamine-based resin, but is not limited thereto.

The resist topcoat composition may further include an additive including a surfactant, a thermal acid generator, a plasticizer, or a combination thereof.

The surfactant may be, for example, an alkylbenzene sulfonic acid salt, an alkylpyridinium salt, polyethylene glycol, a quaternary ammonium salt, and/or the like, but is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and/or other organic sulfonic acid alkyl esters, but is not limited thereto.

The amount of these additives used can be easily adjusted according to suitable or desired physical properties or may be omitted.

The solvent may be an ether-based solvent represented by Chemical Formula 7.

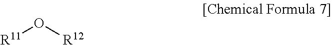

In Chemical Formula 7,
R¹¹ and R¹² are each independently a substituted or unsubstituted C3 to C20 alkyl group.

For example, the ether-based solvent may be selected from diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and a combination thereof.

The ether-based solvent may have suitable or sufficient solubility and/or dispersibility for the aforementioned composition.

According to some example embodiments, a method of forming patterns using the aforementioned photoresist topcoat composition may be provided. For example, the manufactured pattern may be a photoresist pattern.

A method of forming patterns according to some example embodiments includes coating and heating a photoresist composition on a substrate to form a photoresist layer, coating and heating the aforementioned photoresist topcoat composition on the photoresist layer to form a topcoat, and exposing and developing the topcoat and the photoresist layer to form a resist pattern.

Hereinafter, a method of forming patterns using the aforementioned photoresist topcoat composition will be described with reference to the accompanying drawing. The accompanying drawing is a schematic view illustrating a method of forming patterns using a photoresist topcoat composition according to the present disclosure.

Referring to the accompanying drawing, first, an object to be etched is prepared. An example of the object to be etched may be a thin film on a semiconductor substrate. Hereinafter, only embodiments where the object to be etched is a thin film will be described. The surface of the thin film is cleaned to remove contaminants remaining on the thin film. The thin film may be, for example, a silicon nitride film, a polysilicon film, and/or a silicon oxide film.

A photoresist composition is coated on a thin film 100 and heated to form a photoresist layer 101 (1). Subsequently, the photoresist topcoat composition is coated on the photoresist layer and heated to form a photoresist topcoat 30 (2).

The heating may be performed at a temperature of about 80° C. to about 500° C.

Then, the photoresist topcoat and the photoresist layer are exposed to high-energy radiation.

For example, the high-energy radiation that can be used in the exposure process may include light having a high-energy wavelength, such as EUV (Extreme Ultraviolet; wavelength: 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist layer, for example, the region not covered by the patterned mask is changed to a property that is soluble in a developer, so that the exposed region has a different solubility from that of the unexposed region of the photoresist layer.

A photoresist pattern 102b may be formed by dissolving and removing the photoresist layer corresponding to the exposed region and the photoresist topcoat using a developer (3).

In some embodiments, the developer may be an alkaline developer or a developer containing an organic solvent (hereinafter referred to as an organic-based developer).

As the alkaline developer, a quaternary ammonium salt such as, for example, tetramethylammonium hydroxide may be used, but aqueous alkaline solutions such as inorganic alkalis, primary to tertiary amines, alcohol amines, and/or cyclic amines may also be used.

In some embodiments, the alkaline developer may contain alcohol and/or surfactant in a suitable or appropriate amount. An alkaline concentration of the alkaline developer may be, for example, about 0.1 to about 20 mass %, and a pH of the alkaline developer may be, for example, about 10 to about 15.

The organic-based developer may be a developer containing at least one organic solvent selected from the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and the like.

Any suitable solvents generally used in the art may be used as alcohol solvents, amide solvents, ether solvents, and/or hydrocarbon solvents.

A plurality of said solvents may be mixed together, or may be mixed together with solvents or water other than the above-described solvents. A moisture content as a whole of the developer may be suitably or desirably less than about 50 wt %, less than about 20 wt %, less than about 10 wt %, or the developer may be substantially free or completely free of moisture.

A content of the organic solvent may be suitably or desirably about 50 to about 100 wt %, about 80 to about 100 wt %, about 90 to about 100 wt %, or about 95 to about 100 wt % based on a total amount of the organic developer.

The organic developer may include a suitable or appropriate amount of any suitable surfactant as desired.

A content of the surfactant may be about 0.001 to about 5 wt %, about 0.005 to about 2 wt %, or about 0.01 to about 0.5 wt % based on a total amount of the developer.

The organic developer may include an inhibitor.

Subsequently, the exposed thin film is etched by applying the photoresist pattern as an etching mask. As a result, the thin film is formed into a thin film pattern.

The thin film may be etched, for example, by dry etching using an etching gas, and the etching gas may be, for example, CHF₃, CF₄, Cl₂, BCl₃, or a mixture thereof.

In the exposure process performed above, the thin film pattern formed using the photoresist pattern that is formed by the exposure process performed using the EUV light source may have a width corresponding to the photoresist pattern. For example, the photoresist pattern may have a width of about 5 nm to about 100 nm. For example, the thin film pattern formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or may have a width of less than or equal to about 20 nm, like the photoresist pattern.

Hereinafter, embodiments of the present disclosure will be described in more detail through examples relating to the synthesis of the aforementioned polymer and the preparation of a photoresist topcoat composition including the same. However, the present disclosure is not technically limited by the following examples.

### SYNTHESIS EXAMPLES

### Synthesis Example 1: Synthesis of Compound 1a

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (PH₃P) were mixed together in 110 ml of diethylether under a nitrogen atmosphere and then, stirred. After the stirring for 30 minutes, the resultant mixture was cooled down to 0° C., and another mixture of 14.52 g (71.84 mmol) of diisopropyl azodicarboxylate (DIAD) and 35 ml of diethylether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

* ¹H-NMR (Acetone-d6): δ1.90 (3H, t), 4.36 (4H, m), 5.63 (1H, t), 6.09 (1H, t), 8.34 (1H,s)

* ¹⁹F-NMR (Acetone-d6): δ−70.12 (6F, m), −65.38 (6F, m)

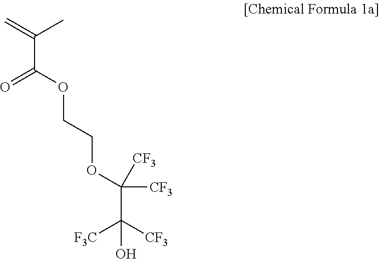 [SMILES: C=C(C)C(=O)OCCOC(C(F)(F)F)(C(F)(F)F)C(O)(C(F)(F)F)C(F)(F)F]

### Synthesis Example 2: Preparation of Copolymer R1

In a 250 mL 2-neck round bottom flask, a compound represented by Chemical Formula 1a (21.06 g, 59 mmol), a compound represented by Chemical Formula 1b (DIHS (di-iodine hydroxyl styrene), Daejeong Chemical Co., Ltd.) (12.20 g, 41 mmol) were added under a nitrogen atmosphere and then, heated to 100° C. When the internal temperature reached 100° C., 18.42 g of a 25 wt % V-601/DIAE solution (V-601, 4.61 g, 30 mmol) was slowly added thereto, and after 6 hours, the resultant reaction solution was cooled to room temperature and then, concentrated to have a solid content of 50%. 270 g of heptane was added to the concentrated solution, and a polymer produced therefrom was filtered. The filtered polymer was completely dissolved in 34 g of DIAE, and 270 g of heptane was added thereto for precipitation, which were twice repeated to obtain precipitates, and the precipitates were completely dried, preparing final Copolymer R1 (Mw=5,000).

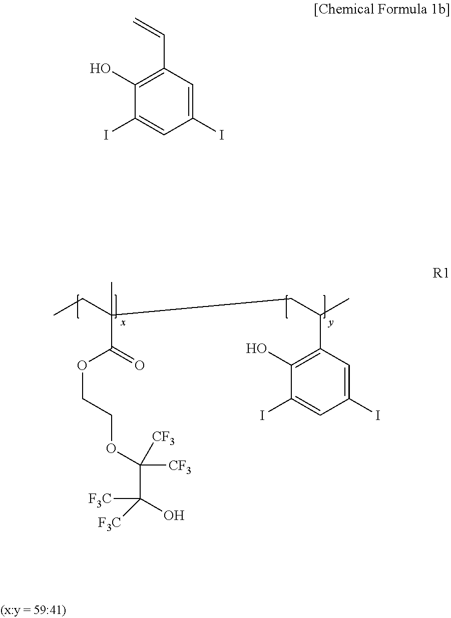

### Synthesis Example 3: Preparation of Copolymer R2

Copolymer R2 (Mw=5,000) was prepared in the same manner as in Synthesis Example 2, except that the compound represented by Chemical Formula 1b was not used.

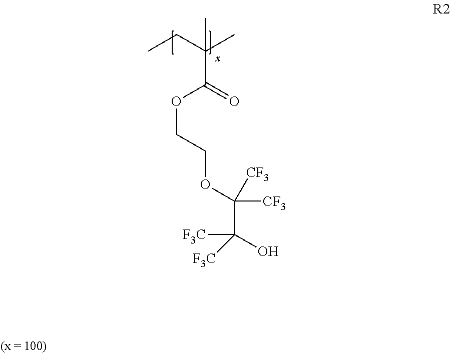

### Preparation of Resist Topcoat Compositions

### Examples 1 to 7 and Comparative Examples 1 to 11

Copolymers R1 and R2 prepared in Synthesis Example 2 and Synthesis Example 3, acidic compounds represented by A1 to A11, and diisoamyl ether (DIAE) were mixed together in the amounts shown in Table 1, stirred at room temperature (23° C.) for 24 hours, and filtered through a Teflon filter with a 0.45 μm pore size to prepare resist topcoat compositions according to according to Examples 1 to 7 and Comparative Examples 1 to 11, respectively.

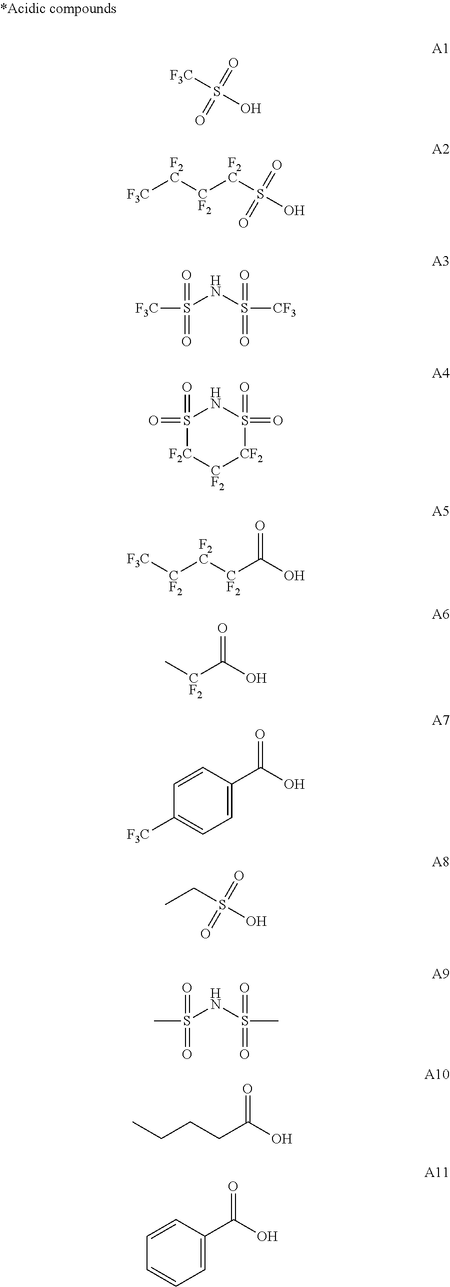

TABLE 1

| | Acidic Compound | | Copolymer | | Solvent | |
|---|---|---|---|---|---|---|
| | | Content | | Content | | Content |
| Composition | Type | (wt %) | Type | (wt %) | Type | (wt %) |
| Example 1 | A1 | 0.2 | R1 | 4.3 | DIAE | 95.5 |
| Example 2 | A2 | 0.4 | R1 | 4.3 | DIAE | 95.3 |
| Example 3 | A3 | 0.4 | R1 | 4.3 | DIAE | 95.3 |
| Example 4 | A4 | 0.4 | R1 | 4.3 | DIAE | 95.3 |
| Example 5 | A5 | 1.3 | R1 | 4.3 | DIAE | 94.4 |
| Example 6 | A6 | 0.9 | R1 | 4.3 | DIAE | 94.8 |
| Example 7 | A7 | 1.3 | R1 | 4.3 | DIAE | 94.4 |
| Comparative | A8 | 0.2 | R1 | 4.3 | DIAE | 95.5 |
| Example 1 | | | | | | |
| Comparative | A9 | 0.4 | R1 | 4.3 | DIAE | 95.3 |
| Example 2 | | | | | | |
| Comparative | A10 | 1.3 | R1 | 4.3 | DIAE | 94.4 |
| Example 3 | | | | | | |
| Comparative | A11 | 1.3 | R1 | 4.3 | DIAE | 94.4 |
| Example 4 | | | | | | |
| Comparative | A1 | 0.2 | R2 | 4.3 | DIAE | 95.5 |
| Example 5 | | | | | | |
| Comparative | A2 | 0.4 | R2 | 4.3 | DIAE | 95.3 |
| Example 6 | | | | | | |
| Comparative | A3 | 0.4 | R2 | 4.3 | DIAE | 95.3 |
| Example 7 | | | | | | |
| Comparative | A4 | 0.4 | R2 | 4.3 | DIAE | 95.3 |
| Example 8 | | | | | | |
| Comparative | A5 | 1.3 | R2 | 4.3 | DIAE | 94.4 |
| Example 9 | | | | | | |
| Comparative | A6 | 0.9 | R2 | 4.3 | DIAE | 94.8 |
| Example 10 | | | | | | |
| Comparative | A7 | 1.3 | R2 | 4.3 | DIAE | 94.4 |
| Example 11 | | | | | | |

### Evaluation 1: Solubility Evaluation

Each of the copolymers of Synthesis Examples 2 to 3 was taken by 1 g and added to 50 g of DIAE (2 wt %) and then, stirred for 24 hours and examined with respect to whether or not precipitates were produced with naked eyes, and the results are shown in Table 2.

(No precipitation—solubility ○, with precipitation—solubility X)

### Evaluation 2: Developability Evaluation

Each of the photoresist topcoat compositions according to Examples and Comparative Examples was spin-coated on a silicon substrate and heat-treated at 110° C. on a hot plate for 1 minute, to form an about 5 nm-thick photoresist topcoat. The substrate with a topcoat formed thereon was developed with 2.38% tetramethylammonium hydroxide aqueous solution and heat-treated again at 110° C. on the hot plate for 1 minute and then, measured with respect to a thickness change of the topcoat layer, and the results are shown in Table 2.

### Evaluation Criteria

* Residual film after development (%)=[Topcoat thickness before development (nm)−Topcoat thickness after development (nm)]×100/Topcoat thickness before development (nm)
(Residual film after development≤20%—Developability O, Residual film after development>20%—Developability X)

### Evaluation 3: Patterning Evaluation

After forming a resist underlayer (thickness: 50 Å) and a photoresist thin film for E-beam (a thickness: 700 Å) on an 8-inch silicon substrate, each of the photoresist topcoat compositions according to the examples and the comparative examples was spin-coated and then, heat-treated at 110° C. for 1 minute on a hot plate to form about 5 nm-thick photoresist topcoats.

The wafer on which the photoresist topcoat was formed was line-printed in Focus-Energy Matrix (FEM) format using E-Beam equipment (JEOL JBX-9300FS). The optimal sensitivity capable of forming a Critical Dimension (CD) of 50 nm was confirmed using the interpolation method, and the results are shown in Table 2.

after checking the optimum sensitivity, a line width roughness (LWR) dispersion at the corresponding energy shot was measured by using CD-SEM equipment made by Hitatchi Ltd., and the same patterns at 500 points were measured within the shot in order to reliability of the dispersion, and final average values thereof are shown in Table 2.

TABLE 2

| | | | Sensitivity | LWR |
|---|---|---|---|---|
| | Solubility | Developability | (μC/cm²) | (nm) |
| Example 1 | ◯ | ◯ | 1550 | 1.96 |
| Example 2 | ◯ | ◯ | 1600 | 1.88 |
| Example 3 | ◯ | ◯ | 1650 | 1.92 |
| Example 4 | ◯ | ◯ | 1650 | 1.90 |
| Example 5 | ◯ | ◯ | 1600 | 1.85 |
| Example 6 | ◯ | ◯ | 1550 | 1.98 |
| Example 7 | ◯ | ◯ | 1600 | 1.93 |
| Comparative | X | X | 2100 | 2.54 |
| Example 1 | | | | |
| Comparative | X | X | 1900 | 2.46 |
| Example 2 | | | | |
| Comparative | X | X | 2000 | 2.48 |
| Example 3 | | | | |
| Comparative | X | X | 2300 | 2.22 |
| Example 4 | | | | |
| Comparative | ◯ | ◯ | 2550 | 2.20 |
| Example 5 | | | | |
| Comparative | ◯ | ◯ | 2500 | 2.12 |
| Example 6 | | | | |
| Comparative | ◯ | ◯ | 2600 | 2.25 |
| Example 7 | | | | |
| Comparative | ◯ | ◯ | 2500 | 2.16 |
| Example 8 | | | | |
| Comparative | ◯ | ◯ | 2450 | 2.55 |
| Example 9 | | | | |
| Comparative | ◯ | ◯ | 2550 | 2.10 |
| Example 10 | | | | |
| Comparative | ◯ | ◯ | 2550 | 2.12 |
| Example 11 | | | | |

Referring to Table 2, if the resist topcoat composition according to Examples 1 to 7 was applied, excellent solubility, developability, sensitivity, and LWR improvement effect also were obtained compared to if applying the resist topcoat composition according to Comparative Examples 1 to 11.

Hereinbefore, example embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure.

### DESCRIPTION OF SYMBOLS

1: forming a photoresist layer
2: forming a photoresist topcoat
3: exposing and developing the photoresist layer and the photoresist topcoat to form a resist pattern
30: photoresist topcoat
100: substrate
101: photoresist layer
102b: photoresist pattern

What is claimed is:

1. A resist topcoat composition, comprising:
the copolymer comprising a copolymer comprising a first structural unit represented by Chemical Formula M-1, a second structural unit represented by Chemical Formula M-2;
at least one acidic compound selected from a sulfonic acid compound containing at least one fluorine, a sulfonimide compound containing at least one fluorine, and a carboxylic acid compound containing at least one fluorine; and
a solvent: 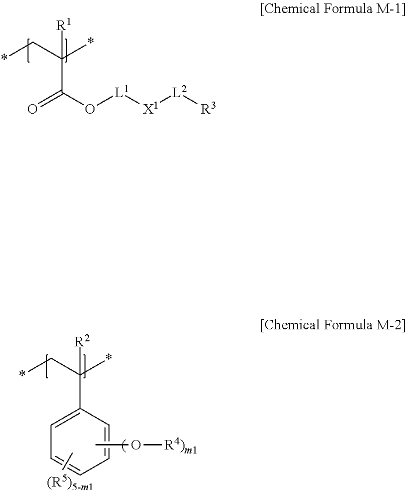
wherein, in Chemical Formula M-1 and Chemical Formula M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen or C(═O)R^{b},
R^{b} is a substituted or unsubstituted C1 to C10 alkyl group,
at least one selected from R³, L¹, and L² comprises fluorine and a hydroxy group,
R⁵ is hydrogen, a halogen, a hydroxy group, a substituted or unsubstituted C1 to C10 alkyl group, or a combination thereof,
m1 is one of integers of 1 to 4, and
* is a linking point.

2. The resist topcoat composition as claimed in claim 1, wherein:
the copolymer and the acidic compound are included in a weight ratio of about 3:1 to about 30:1.

3. The resist topcoat composition as claimed in claim 1, wherein:
the copolymer is included in an amount of about 1 wt % to about 10 wt % based on a total weight of the resist topcoat composition.

4. The resist topcoat composition as claimed in claim 1, wherein:
the acidic compound is included in an amount of about 0.1 wt % to about 3 wt % based on a total weight of the resist topcoat composition.

5. The resist topcoat composition as claimed in claim 1, wherein:
the first structural unit is represented by Chemical Formula 1: 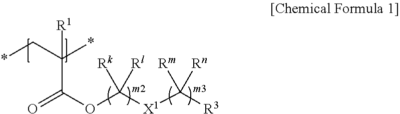
wherein, in Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently one of integers of 1 to 10,
X¹ is a single bond, —O—, —S—, —S(O)—, —S(O)₂—, —C(O)—, —(CO)O—, —O(CO)—, —O(CO)O—, —NR^{a}— (wherein, R^{a} is hydrogen, deuterium, or a substituted or unsubstituted C1 to C10 alkyl group), or a combination thereof, and
at least one selected from R^{k}, R^{l}, R^{m}, Rⁿ, and R³ comprises fluorine and a hydroxy group.

6. The resist topcoat composition as claimed in claim 1, wherein:
the first structural unit is at least one selected from Group I: 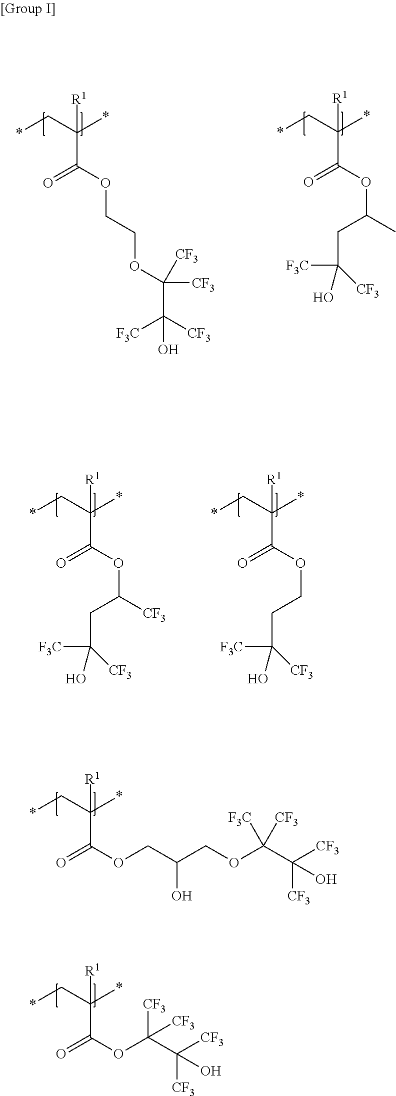
wherein, in Group I,
R¹ is each independently hydrogen or a methyl group, and * is a linking point.

7. The resist topcoat composition as claimed in claim 1, wherein:
the second structural unit is represented by any one selected from Chemical Formula 2-1 to Chemical Formula 2-4: 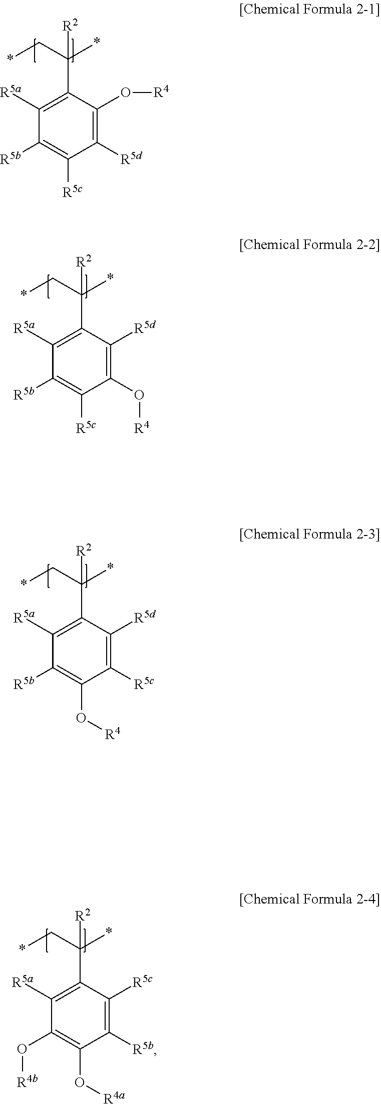
wherein, in Chemical Formula 2-1 to Chemical Formula 2-4,
R² is hydrogen or a methyl group,
R⁴, R^{4a}, and R^{4b} are each independently hydrogen or C(═O)R^{b},
R^{b} is a substituted or unsubstituted C1 to C5 alkyl group,
R^{5a}, R^{5b}, R^{5c}, and R^{5d} are each independently hydrogen, a halogen, a hydroxy group, a substituted or unsubstituted C1 to C10 alkyl group, or a combination thereof, and
* is a linking point.

8. The resist topcoat composition as claimed in claim 1, wherein:
the second structural unit is at least one selected from Group II: 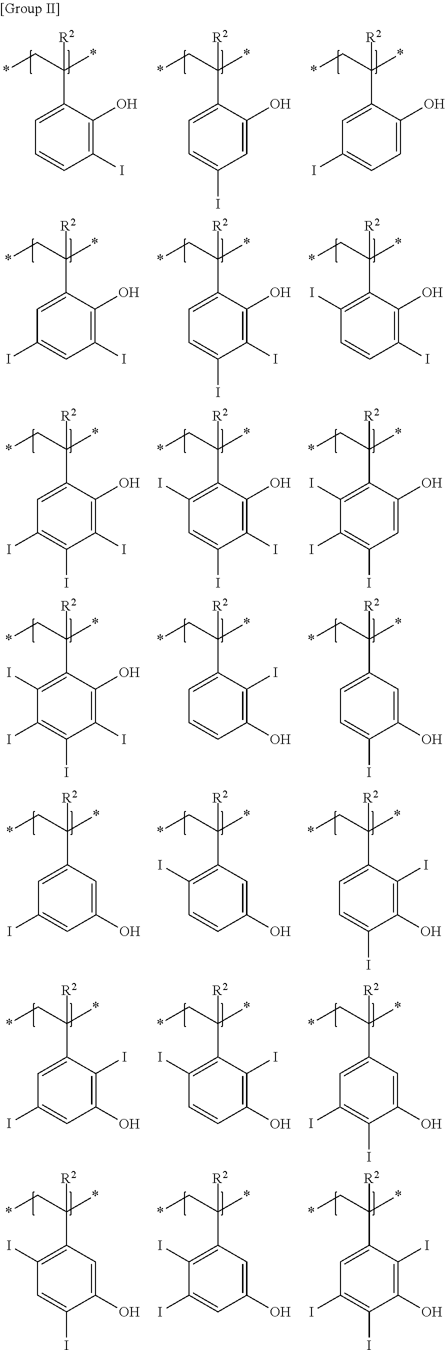 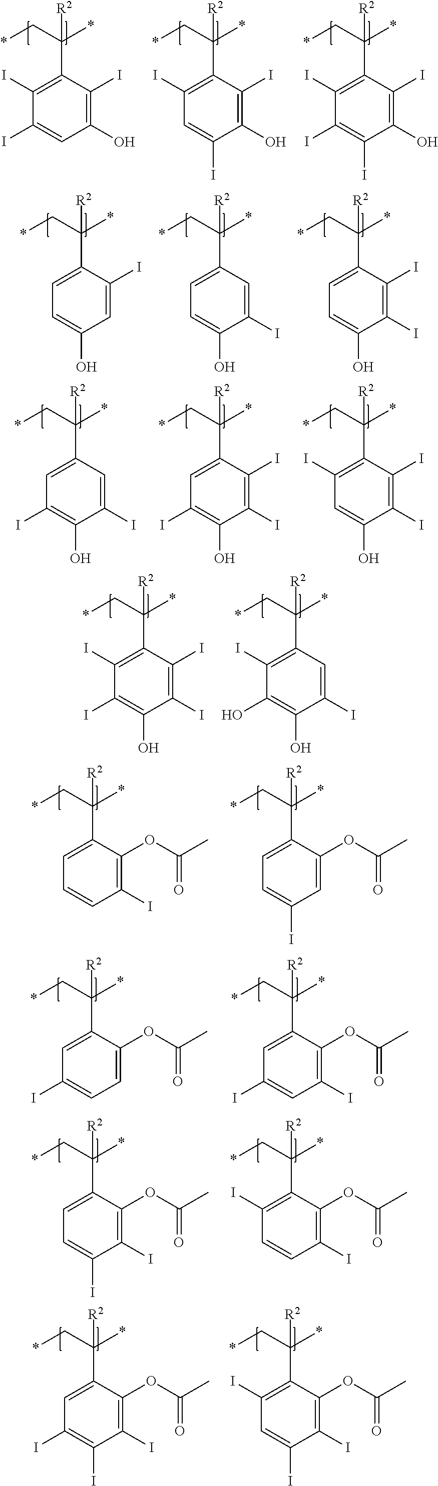 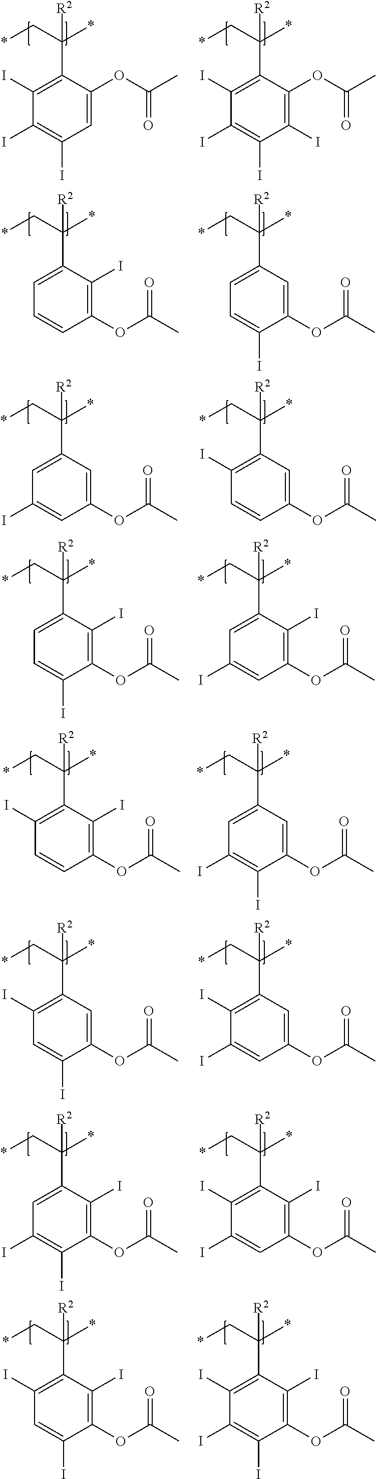 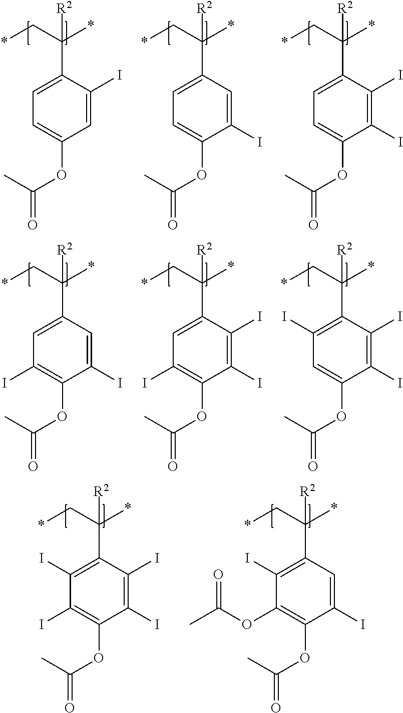
wherein, in Group II,
R² is each independently hydrogen or a methyl group and * is a linking point.

9. The resist topcoat composition as claimed in claim 1, wherein:
the copolymer includes about 30 to about 95 mol % of the first structural unit and about 5 to about 70 mol % of the second structural unit.

10. The resist topcoat composition as claimed in claim 1, wherein:
the copolymer has a weight average molecular weight of about 1,000 g/mol to about 50,000 g/mol.

11. The resist topcoat composition as claimed in claim 1, wherein:
the acidic compound is at least one selected from compounds represented by Chemical Formula 3 to Chemical Formula 6: 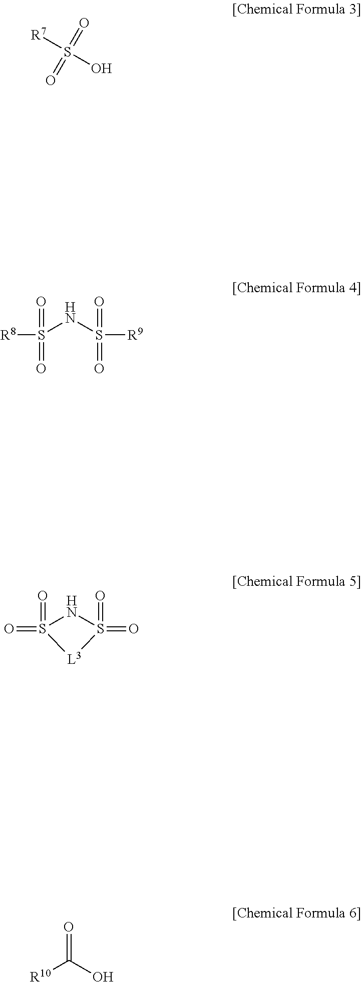
wherein, in Chemical Formula 3 to Chemical Formula 6,
R⁷ to R¹⁰ are each independently fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, a C1 to C20 heteroaryl group substituted with at least one fluorine, or a combination thereof, and
L³ is a C1 to C10 alkylene group substituted with at least one fluorine, a C3 to C20 cycloalkylene group substituted with at least one fluorine, a C6 to C20 arylene group substituted with at least one fluorine, a C1 to C20 heteroarylene group with at least one fluorine, or a combination thereof.

12. The resist topcoat composition as claimed in claim 1, wherein:
the acidic compound is at least one selected from compounds listed in Group IV:

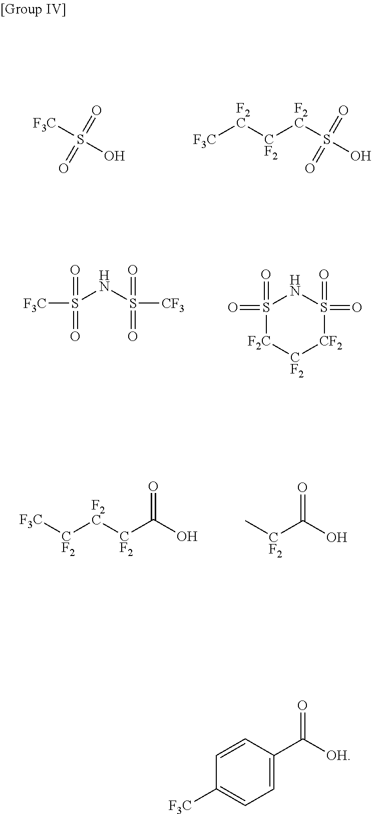

13. A method of forming patterns, comprising:
coating and heating a photoresist composition on a substrate to form a photoresist layer,
coating and heating the resist topcoat composition as claimed in claim 1 on the photoresist layer to form a topcoat, and
exposing and developing the topcoat and the photoresist layer to form a resist pattern.
